(19) United States
(12) Patent Application Publication
(10) Pub. No.: US 2019/0301866 A1
(43) Pub. Date: Oct. 3, 2019

(54) PHYSICAL QUANTITY SENSOR

(71) Applicant: DENSO CORPORATION, Kariya-city (JP)

(72) Inventors: Takeru KANAZAWA, Kariya-city (JP); Minekazu SAKAI, Kariya-city (JP); Naoki YOSHIDA, Kariya-city (JP); Kiyomasa SUGIMOTO, Kariya-city (JP); Nobuaki KUZUYA, Kariya-city (JP)

(21) Appl. No.: 16/444,160

(22) Filed: Jun. 18, 2019

Related U.S. Application Data
(62) Division of application No. 15/308,866, filed on Nov. 4, 2016.

(30) Foreign Application Priority Data
Jun. 12, 2014 (JP) 2014-121688

(51) Int. Cl. G01C 19/5621; H01L 41/08; G01C 19/5783; B81B 7/02; H01L 41/313; H01L 41/311; H01L 41/113; H01L 41/053; G01P 15/125; G01C 19/5628

(52) U.S. Cl. CPC G01C 19/5621; H01L 41/0825; G01C 19/5783; B81B 7/02; H01L 41/313; G01P 2015/0814; H01L 41/113; H01L 41/053; G01P 15/125; G01C 19/5628; H01L 41/311

(57) ABSTRACT

Within a housing portion in which a recessed portion is formed, a circuit board is arranged on the bottom surface of the recessed portion, through a first connecting member. An acceleration sensor is stacked on the circuit board, through a second connecting member. Hence, sections that function as three or more springs, i.e., an anti-vibration portion, the first connecting member, and the second connecting member, are situated between an angular velocity sensor and the acceleration sensor. For this reason, transmission of vibration of the vibrating element in the angular velocity sensor to the acceleration sensor can be restricted, and reduction in the detection accuracy of the acceleration sensor can be restricted.

### CROSS REFERENCE TO RELATED APPLICATIONS

This application is a divisional application of U.S. application Ser. No. 15/308,866 filed on Nov. 4, 2016, which is a U.S. national stage application of International Patent Application No. PCT/JP2015/002921 filed on Jun. 11, 2015 and is based on Japanese Patent Application No. 2014-121688 filed on Jun. 12, 2014, the disclosures of which are incorporated herein by reference.

### TECHNICAL FIELD

The present disclosure relates to a physical quantity sensor including an acceleration sensor provided with a sensing portion outputting a sensor signal corresponding to acceleration and an angular velocity sensor provided with a sensing portion outputting a sensor signal corresponding to an angular velocity, both of which are housed in a housing space of a common case.

### BACKGROUND

A physical quantity sensor disclosed in the related art includes an acceleration sensor provided with a sensing portion outputting a sensor signal corresponding to acceleration and an angular velocity sensor provided with a sensing portion outputting a sensor signal corresponding to an angular velocity, both of which are housed in a housing space of a common case (see, for example, Patent Literature 1).

More specifically, the case has a housing portion in which a recessed portion is provided and a lid portion provided to the housing portion so as to close the recessed portion, and the housing space is defined by the recessed portion provided in the housing portion. The acceleration sensor is arranged on a bottom surface of the recessed portion in the housing portion. The angular velocity sensor is held in midair in the housing space of the case by an outer portion having an anti-vibration portion (spring portion). Further, a circuit board having a drive signal circuit driving the acceleration sensor and the angular velocity sensor, a signal processing circuit processing sensor signals outputted by the angular velocity sensor and the acceleration sensor, and so on is arranged on the bottom surface of the housing portion. The acceleration sensor and the circuit board are electrically connected through a bonding wire and the angular velocity sensor and the circuit board are electrically connected through an inner-layer wiring or the like provided inside the case.

The angular velocity senor used in the related art has a vibrating element. When an angular velocity is applied while the vibrating element is vibrating, the angular velocity sensor outputs charges generated in response to the angular velocity as a sensor signal. The acceleration sensor used in the related art has, for example, a movable electrode and a fixed electrode opposing the movable electrode. When the acceleration is applied, the acceleration sensor outputs a capacitance between the movable electrode and the fixed electrode that varies with acceleration as a sensor signal.

### PATENT LITERATURE

Patent Literature 1: JP2013-101132A

### SUMMARY

In the physical quantity sensor as above, the angular velocity sensor is held by the outer portion having the anti-vibration portion. Nevertheless, vibrations of the vibrating element in the angular velocity sensor may possibly be transmitted to the case. When the vibrations are further transmitted from the case to the acceleration sensor, detection accuracy of the acceleration sensor may be reduced.

Also, the acceleration sensor and the circuit board are individually arranged on the bottom surface of the recessed portion in the housing portion and installed a predetermined distance apart. Hence, the bonding wire (transmission path of sensor signals) electrically connecting the acceleration sensor and the circuit board is likely to extend and a parasitic capacitance generated in the bonding wire tends to increase. Accordingly, the parasitic capacitance has a significant influence when a sensor signal from the acceleration sensor is processed in the circuit board and detection accuracy may possibly be deteriorated.

In view of the foregoing difficulties, an object of the present disclosure is to provide a physical quantity sensor including an acceleration sensor and an angular velocity sensor both housed in a case and capable of restricting reduction in detection accuracy of the acceleration sensor.

According to an aspect of the present disclosure, the physical quantity sensor includes an acceleration sensor outputting a sensor signal corresponding to acceleration, an angular velocity sensor having a vibrating element made of a piezoelectric material and generating charges corresponding to an angular velocity when the angular velocity is applied while the vibration element is vibrating and outputting a sensor signal corresponding to the charges, a circuit board performing predetermined processing on the angular velocity sensor and the acceleration sensor, a housing portion provided with a recessed portion in a surface of the housing portion to house the acceleration sensor, the angular velocity sensor, and the circuit board in the recessed portion, and an anti-vibration portion situated between the housing portion and the vibrating element in the angular velocity sensor. The angular velocity sensor and the acceleration sensor are spaced apart.

The circuit board is arranged on a bottom surface of the recessed portion through a first connecting member, the acceleration sensor is stacked on the circuit board through a second connecting member, and the acceleration sensor is a vibrating system at three degrees of freedom in reference to the angular velocity sensor.

Hence, the anti-vibration portion, the first connecting member, and the second connecting member are arranged between the angular velocity sensor and the acceleration sensor, and members functioning as springs arranged between the angular velocity sensor and the acceleration sensor can be increased (Refer to FIGS. 7 and 10). Hence, transmission of vibrations of the vibrating element in the angular velocity sensor to the acceleration sensor can be restricted. Consequently, reduction in detection accuracy of the acceleration sensor can be restricted.

By stacking the acceleration sensor on the circuit board, the acceleration sensor and the circuit board can be arranged in close proximity to each other. In short, a transmission path of sensor signals outputted by the acceleration sensor can be shorter. Hence, an increase of a parasitic capacitance generated in the transmission path can be restricted. Consequently, reduction in detection accuracy of the acceleration sensor can be restricted.

### BRIEF DESCRIPTION OF DRAWINGS

The above and other objects, features and advantages of the present disclosure will become more apparent from the following detailed description made with reference to the accompanying drawings. In the drawings:

FIG. 1 is a sectional view of a physical quantity sensor according to a first embodiment of the present disclosure;

FIG. 2 is a sectional view of an acceleration sensor shown in FIG. 1;

FIG. 3 is a top view of a sensor portion shown in FIG. 2;

FIG. 4 is a top view of an angular velocity sensor shown in FIG. 1;

FIG. 5 is a view corresponding to a section taken along the line V-V of FIG. 4;

FIG. 6 shows a spring mass model of a physical quantity sensor in the related art;

FIG. 7 is a spring mass model of the physical quantity sensor shown in FIG. 1;

FIG. 8 is a sectional view of a physical quantity sensor according to a second embodiment of the present disclosure;

FIG. 9 is a sectional view of a physical quantity sensor according to a third embodiment of the present disclosure;

FIG. 10 shows a spring mass model of the physical quantity sensor shown in FIG. 9;

FIG. 11 is a sectional view of a physical quantity sensor according to a fourth embodiment of the present disclosure; and

FIG. 12 is a top view of an angular velocity sensor according to a fifth embodiment of the present disclosure.

### DETAILED DESCRIPTION

Hereafter, referring to drawings, embodiments of the present invention will be described. In addition, the substantially same parts and components are indicated with the same reference numeral and will be described in following embodiments.

### First Embodiment

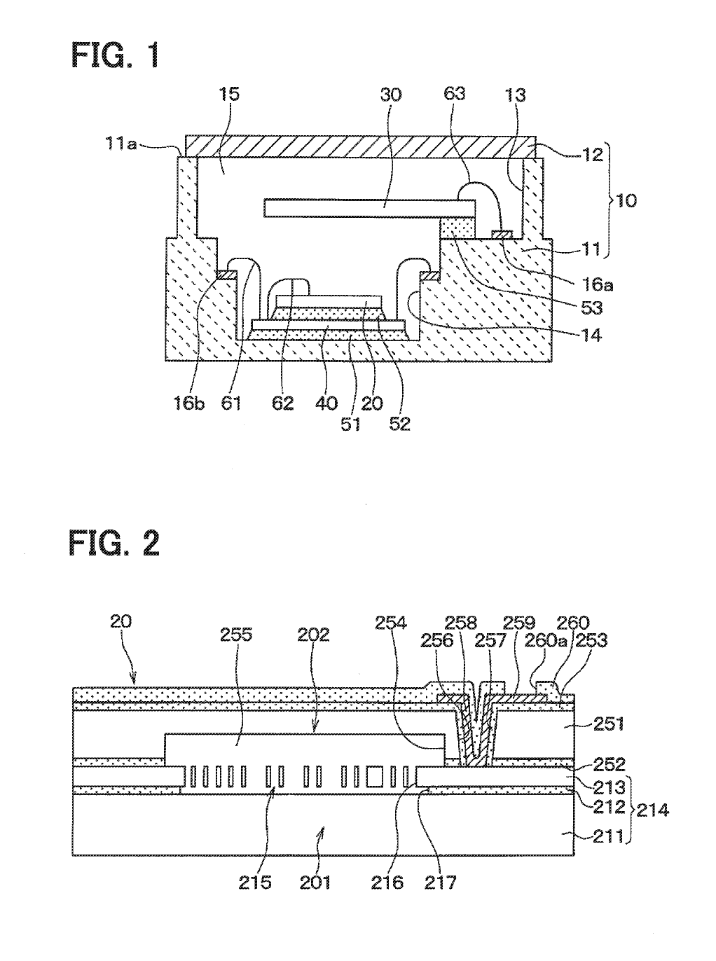

A first embodiment of the present disclosure will be described with reference to the drawings. As is shown in FIG. 1, a physical quantity sensor includes a case 10 and the case 10 has a housing portion 11 and a lid portion 12.

The housing portion 11 is formed by stacking multiple ceramic layers made of alumina or the like and shaped like a box in which a housing space 15 is defined by providing a first recessed portion 13 in a surface 11a and by providing a second recessed portion 14 in a bottom surface of the first recessed portion 13. In the housing portion 11, internal connecting terminals 16a and 16b are provided to inner wall surfaces (a wall surface of the first recessed portion 13 and a wall surface of the second recessed portion 14) and unillustrated external connecting terminals are provided to outer wall surfaces.

The internal connecting terminals 16a and 16b and the external connecting terminals are electrically connected as needed by an unillustrated inner-layer wiring or the like provided inside.

The lid portion 12 is made of metal or the like and bonded to the surface 11a of the housing portion 11 by welding or the like to hermetically seal the housing space 15. In the present embodiment, the housing space 15 is set to a vacuum pressure, for example, 1 Pa.

An acceleration sensor 20, an angular velocity sensor 30, and a circuit board 40 having a drive signal circuit driving the acceleration sensor 20 and the angular velocity sensor 30, a signal processing circuit processing respective sensor signals, and so on are housed in the housing space 15 of the case 10. More specifically, the circuit board 40 is arranged on a bottom surface of the second recessed portion 14 through an adhesive agent 51 and the acceleration sensor 20 is stacked on the circuit board 40 through an adhesive agent 52. The circuit board 40 is electrically connected to the internal connecting terminal 16b through a bonding wire 61 and the acceleration sensor 20 is electrically connected to the circuit board 40 through a bonding wire 62.

The angular velocity sensor 30 is arranged on the bottom surface of the first recessed portion 13 through an adhesive agent 53. To be more specific, the angular velocity sensor 30 has an outer peripheral portion 313 and the outer peripheral portion 313 is bonded to the adhesive agent 53. The angular velocity sensor 30 is electrically connected to the internal connecting terminal 16a through a bonding wire 63.

In the present embodiment, the angular velocity sensor 30 is spaced apart from the acceleration sensor 20 and arranged above the acceleration sensor 20. The angular velocity sensor 30 is held in midair in the housing space 15.

A silicone-based adhesive agent or the like is used as the adhesive agents 51 to 53. In the present embodiment, the adhesive agent 51 corresponds to a first connecting member, the adhesive agent 52 corresponds to a second connecting member, and the adhesive agent 53 corresponds to an anti-vibration portion.

The acceleration sensor 20 is of a package structure sealed at an atmospheric pressure and installed in the housing space 15 in a packaged state. The angular velocity sensor 30 is directly installed in the housing space 15. Hence, the acceleration sensor 20 detects acceleration under an atmospheric pressure whereas the angular velocity sensor 30 detects an angular velocity under a vacuum pressure.

A configuration of the acceleration sensor 20 and a configuration of the angular velocity sensor 30 of the present embodiment will now be described.

As is shown in FIG. 2, the acceleration sensor 20 is of a package structure including a sensor portion 201 and a cap portion 202.

The sensor portion 201 is formed by using an SOI (Silicon on Insulator) substrate 214 made up of a supporting substrate 211, an insulating film 212, and a semiconductor layer 213, which are stacked sequentially. The supporting substrate 211 and the semiconductor layer 213 are formed of a silicon substrate or the like and the insulating film 212 is formed of an oxide film or the like.

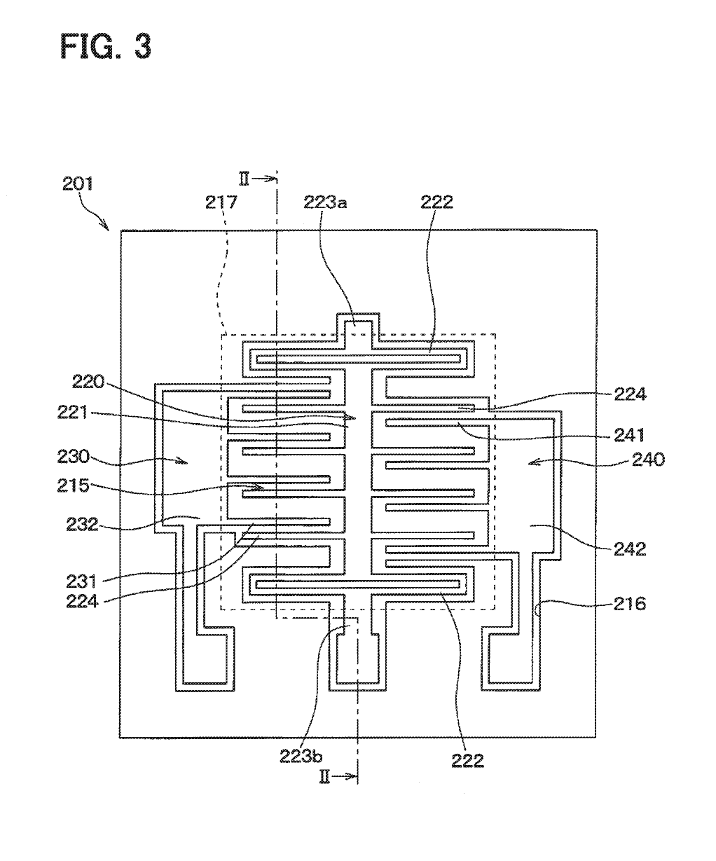

As are shown in FIG. 2 and FIG. 3, the SOI substrate 214 is micro-machined in a known manner and a sensing portion 215 is provided. More specifically, by providing a groove portion 216 to the semiconductor layer 213, a movable portion 220, a first fixed portion 230, and a second fixed portion 240 each having a comb-teeth beam structure are provided, and the three beam structures together form the sensing portion 215 outputting a sensor signal corresponding to acceleration.

An opening portion 217 of a rectangular shape is provided to the insulating film 212 by removing a portion corresponding to regions where the beam structures 220, 230, and 240 are provided by sacrifice layer etching or the like.

The movable portion 220 is arranged so as to cross the opening portion 217 and both ends of a weight portion 221 in a longitudinal direction are integrally joined to anchor portions 223a and 223b through beam portions 222. The weight portion 221 is a rectangular shape. The anchor portions 223a and 223b are supported on the supporting substrate 211 through the insulating film 212 at an opening edge portion along the opening portion 217. Consequently, the weight portion 221 and the beam portions 222 face the opening portion 217. The sensor portion 201 of FIG. 2 corresponds to a sectional view taken along the line II-II of FIG. 3.

Each beam portion 222 includes two parallel beams joined at both ends in a rectangular frame shape and has a spring function to displace in a direction orthogonal to a longitudinal direction of the two beams. More specifically, when the beam portion 222 undergoes acceleration including a component in a direction along the longitudinal direction of the weight portion 221, the beam portion 222 forces the weight portion 221 to displace in the longitudinal direction and also allows the weight portion 221 to restore to an original state when acceleration vanishes. Hence, when acceleration is applied, the weight portion 221 joined to the supporting substrate 211 through the beam portions 222 configured as above displaces in a displacement direction of the beam portions 222.

The movable portion 220 includes multiple movable electrodes 224 provided integrally with the weight portion 221 to protrude oppositely to each other from both side surfaces in a direction orthogonal to the longitudinal direction of the weight portion 221. In FIG. 3, the four movable electrodes 224 are provided to protrude from each of a left side and a right side of the weight portion 221 and all of the movable electrodes 224 face the opening portion 217. The respective movable electrodes 224 are provided integrally with the weight portion 221 and the beam portions 222. Hence, when the beam portions 222 displace, the movable electrodes 224 can displace in the longitudinal direction of the weight portion 221 together with the weight portion 221.

The first fixed portion 230 and the second fixed portion 240 are supported on the supporting substrate 211 through the insulating film 212 at the opening edge portion along the opening portion 217 in opposing side portions where the anchor portions 223a and 223b are not supported. In short, the first fixed portion 230 and the second fixed portion 240 are arranged with the movable portion 220 in between. In FIG. 3, the first fixed portion 230 is arranged on a left side on a sheet surface with respect to the movable portion 220 and the second fixed portion 240 is arranged on a right side on the sheet surface with respect to the movable portion 220. The first fixed portion 230 and the second fixed portion 240 are electrically independent from each other. The first fixed portion 230 and the second fixed portion 240 respectively have multiple first fixed electrodes 231 and multiple second fixed electrodes 241 arranged oppositely parallel to side surfaces of the movable electrodes 224 at predetermined detection intervals and a first wiring portion 232 and a second wiring portion 242 both supported on the supporting substrate 211 through the insulating film 212.

In FIG. 3, the four first fixed electrodes 231 and the four second fixed electrodes 241 are provided and aligned like comb teeth to mesh with clearances among comb teeth of the movable electrodes 224. The first fixed electrodes 231 and the second fixed electrodes 241 are supported, respectively, on the wiring portions 232 and 242 like a cantilever and therefore face the opening portion 217. The above has described the configuration of the sensor portion 201 of the present embodiment.

As is shown in FIG. 2, the cap portion 202 includes an insulating film 252 provided to a substrate 251 made of silicon or the like on a surface of the substrate 251 opposing the sensor portion 201 and an insulating film 253 provided to the other surface of the substrate 251 opposite to the surface of the substrate 251.

In the cap portion 202, the insulating film 252 is bonded to the sensor portion 201 (semiconductor layer 213). In the present embodiment, the insulating film 252 and the sensor portion 201 (semiconductor layer 213) are bonded by, for example, so-called direct bonding by which the insulating film 252 and the semiconductor layer 213 are bonded by activating respective bond surfaces.

A dent portion 254 is also provided to the cap portion 202 in a portion opposing the sensing portion 215. An airtight chamber 255 is defined between the sensor portion 201 and the cap portion 202 by a space including the dent portion 254. The sensing portion 215 provided to the sensor portion 201 is hermetically sealed in the airtight chamber 255. In the present embodiment, the airtight chamber 255 is set to an atmospheric pressure. That is to say, in the present embodiment, the acceleration sensor 20 is of a package structure in which the sensing portion 215 is hermetically sealed in the airtight chamber 255 set to an atmospheric pressure.

In addition, multiple through-holes 256 (only one through-hole 256 is shown in FIG. 2) are provided to penetrate through the cap portion 202 in a stacking direction of the cap portion 202 and the sensor portion 201. More specifically, the respective through-holes 256 are provided to expose predetermined parts of the anchor portion 223b, the first wiring portion 232, and the second wiring portion 242. An insulating film 257 made of TEOS (tetraethyl orthosilicate) or the like is deposited on a wall surface of each through-hole 256. A through-hole electrode 258 made of Al or the like is provided on the insulating film 257 and electrically connected to the anchor portion 223b, the first wiring portion 232, and/or the second wiring portion 242 as needed. Further, a pad portion 259 electrically connected to the circuit board 40 is provided on the insulating film 253.

A protection film 260 is provided on the insulating film 253, the through-hole electrode 258, and the pad portion 259. The protection film 260 is provided with a contact hole 260a through which the pad portion 259 is exposed.

The above has described the configuration of the acceleration sensor 20. When acceleration is applied to the acceleration sensor 20 configured as above, the weight portion 221 displaces in response to the acceleration and capacitances between the movable electrodes 224 and the first fixed electrodes 231 and between the movable electrodes 224 and the second fixed electrodes 241 vary with such displacement. Hence, a sensor signal corresponding to the acceleration (capacitances) is outputted by the acceleration sensor 20.

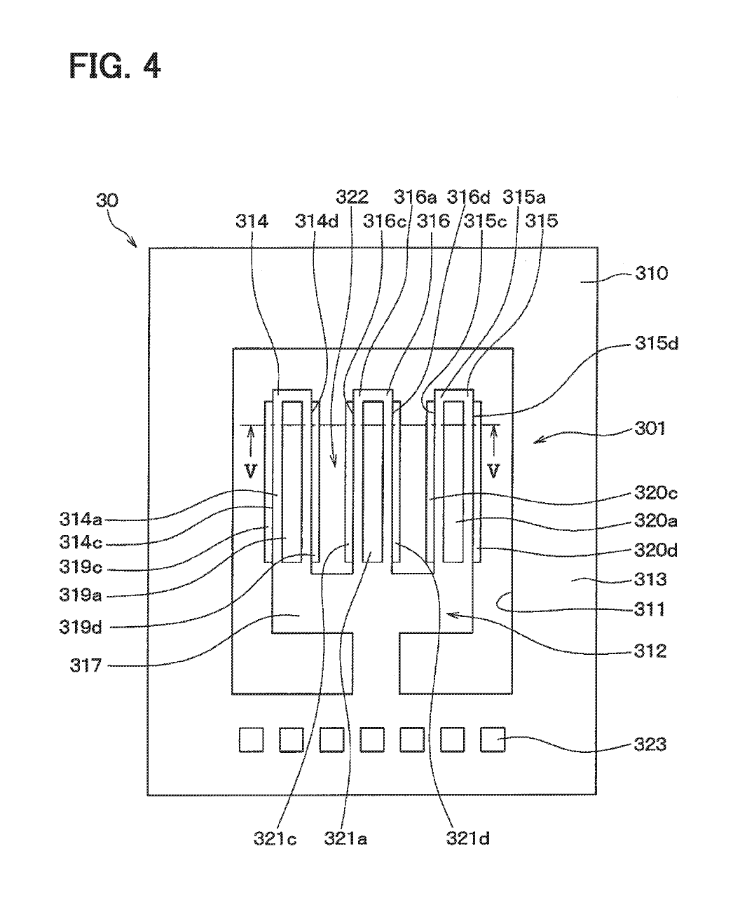

A configuration of the angular velocity sensor 30 will now be described. As is shown in FIG. 4, the angular velocity sensor 30 includes a sensor portion 301 formed by using a substrate 310 made of a piezoelectric material, such as crystal and PZT (lead zirconate titanate). The substrate 310 is micro-machined in a known manner and a groove portion 311 is provided. The substrate 310 is divided by the groove portion 311 to a part where a vibrating element 312 is provided and a part where the outer peripheral portion 313 is provided.

The vibrating element 312 includes a first drive reed 314, a second drive reed 315, and a detection reed 316, all of which are held by a base portion 317, and the base portion 317 is fixed to the outer peripheral portion 313. To be more specific, the vibrating element 312 is a so-called tripod-type tuning fork in which the first drive reed 314, the second drive reed 315, and the detection reed 316 protrude from the base portion 317 in a same direction, and the detection reed 316 is situated between the first drive reed 314 and the second drive reed 315.

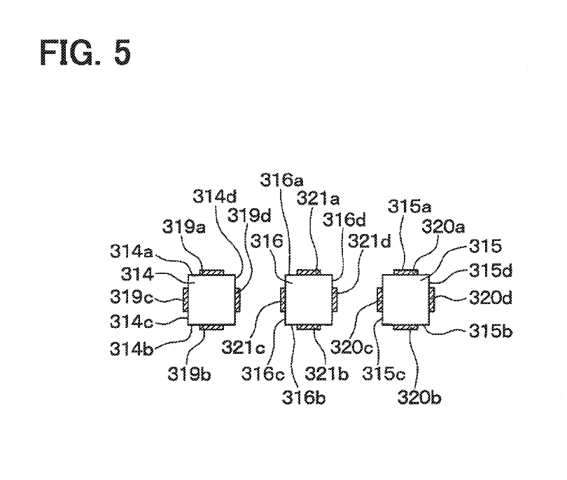

As are shown in FIG. 4 and FIG. 5, the first drive reed 314, the second drive reed 315, and the detection reed 316 are shaped like rods with a rectangular cross section having surfaces 314a, 315a, and 316a and rear surfaces 314b, 315b, and 316b each parallel to plane directions of the substrate 310, and side surfaces 314c and 314d, 315c and 315d, and 316c and 316d, respectively.

In the first drive reed 314, a drive electrode 319a is provided to the surface 314a, a drive electrode 319b is provided to the rear surface 314b, and common electrodes 319c and 319d are provided to the side surfaces 314c and 314d, respectively. Likewise, in the second drive reed 315, a drive electrode 320a is provided to the surface 315a, a drive electrode 320b is provided to the rear surface 315b, and common electrodes 320c and 320d are provided to the side surfaces 315c and 315d, respectively. Also, in the detection reed 316, a detection electrode 321a is provided to the surface 316a, a detection electrode 321b is provided to the rear surface 316b, and common electrodes 321c and 321d are provided to the side surfaces 316c and 316d, respectively.

In the present embodiment, the first drive reed 314, the second drive reed 315, the detection reed 316, the drive electrodes 319a to 320b, the detection electrodes 321a and 321b, and the common electrodes 319c to 321d together form a sensing portion 322.

As is shown in FIG. 4, the outer peripheral portion 313 is provided with multiple pad portions 323 electrically connected to the drive electrodes 319a to 320b, the detection electrodes 321a and 321b, and the common electrodes 319c to 321d through unillustrated wiring layers or the like and also electrically connected to the circuit board 40.

The above has described the configuration of the angular velocity sensor 30. That point is that the sensing portion 322 in the angular velocity sensor 30 of the present embodiment is not hermetically sealed in an airtight chamber. The angular velocity sensor 30 as above detects an angular velocity while the first drive reed 314 and the second drive reed 315 are vibrating in an alignment direction of the first drive reed 314, the second drive reed 315, and the detection reed 316 (a right-left direction on a sheet surface of FIG. 4).

When an angular velocity is applied within a plane of the sensor portion 301, a pair of Coriolis forces develop at the first drive reed 314 and the second drive reed 315 periodically in opposite orientations in a direction along the protruding direction of the first drive reed 314 and the second drive reed 315 with respect to the base portion 317. Hence, moments induced by the Coriolis forces are transmitted to the detection reed 316 through the base portion 317 and the detection reed 316 starts to vibrate (bend) in the alignment direction of the first drive reed 314, the second drive reed 315, and the detection reed 316. Eventually, charges corresponding to the angular velocity are generated at the detection reed 316. A sensor signal corresponding to the angular velocity (charges) is thus outputted by the angular velocity sensor 30.

When an angular velocity is not applied, moments applied from the first drive reed 314 and the second drive reed 315 to the detection reed 316 through the base portion 317 are in opposite directions and therefore cancelled out with each other. Hence, the detection reed 316 is substantially at rest.

The above has described the configuration of the physical quantity sensor of the present embodiment. In the physical quantity sensor configured as above, because the acceleration sensor 20 is arranged on the circuit board 40, transmission of vibrations of the vibrating element 312 in the angular velocity sensor 30 to the acceleration sensor 20 can be restricted.

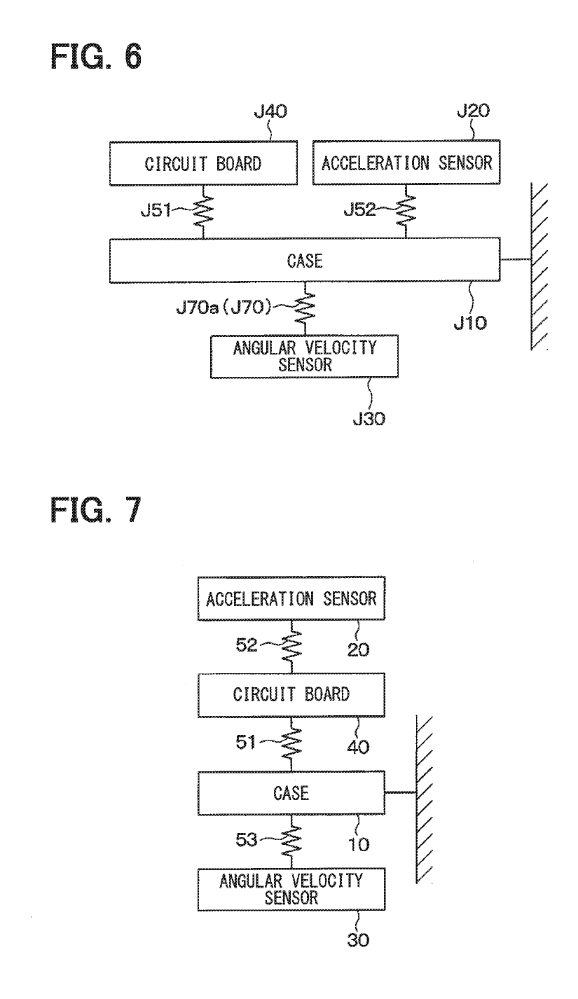

That is to say, in a physical quantity sensor in the related art, an acceleration sensor and a circuit board are individually arranged on a bottom surface of a second recessed portion. Hence, as is shown in FIG. 6, an acceleration sensor J20 is connected to a case J10 through a connecting member J52, an angular velocity sensor J30 is connected to the case J10 through a spring portion J70a of an outer portion J70, and a circuit board J40 is connected to the case J10 through a connecting member J51. In short, sections that function as two springs, namely, the spring portion J70a of the outer portion J70 and the connecting member J52 are situated between the angular velocity sensor J30 and the acceleration sensor J20. In other words, in reference to the angular velocity sensor J30, the acceleration sensor J20 is a vibrating system at two degrees of freedom.

In contrast, as is shown in FIG. 7, in the physical quantity sensor of the present embodiment, sections that function as three springs, namely, the adhesive agent 53, the adhesive agent 51, and the adhesive agent 52 are situated between the angular velocity sensor 30 and the acceleration sensor 20. In short, in reference to the angular velocity sensor 30, the acceleration sensor 20 is a vibrating system at three degrees of freedom. Consequently, transmission of vibrations of the vibrating element 312 in the angular velocity sensor 30 to the acceleration sensor 20 can be restricted and hence reduction in detection accuracy of the acceleration sensor 20 can be restricted.

By stacking the acceleration sensor 20 on the circuit board 40, the acceleration sensor 20 and the circuit board 40 can be arranged in close proximity to each other. In short, the bonding wire 62 connecting the acceleration sensor 20 and the circuit board 40 can be shorter. In other words, a transmission path of sensor signals outputted by the acceleration sensor 20 can be shorter. Hence, an increase of a parasitic capacitance generated in the bonding wire 62 can be restricted. Consequently, reduction in detection accuracy of the acceleration sensor 20 can be restricted.

In addition, the angular velocity sensor 30 is arranged above the acceleration sensor 20. Hence, an increase of the physical quantity sensor in size in the plane directions can be restricted.

### Second Embodiment

A second embodiment of the present disclosure will be described. The present embodiment is same as the first embodiment above except that the bonding wire 62 of the first embodiment above is omitted, and a description other than such a difference is omitted herein.

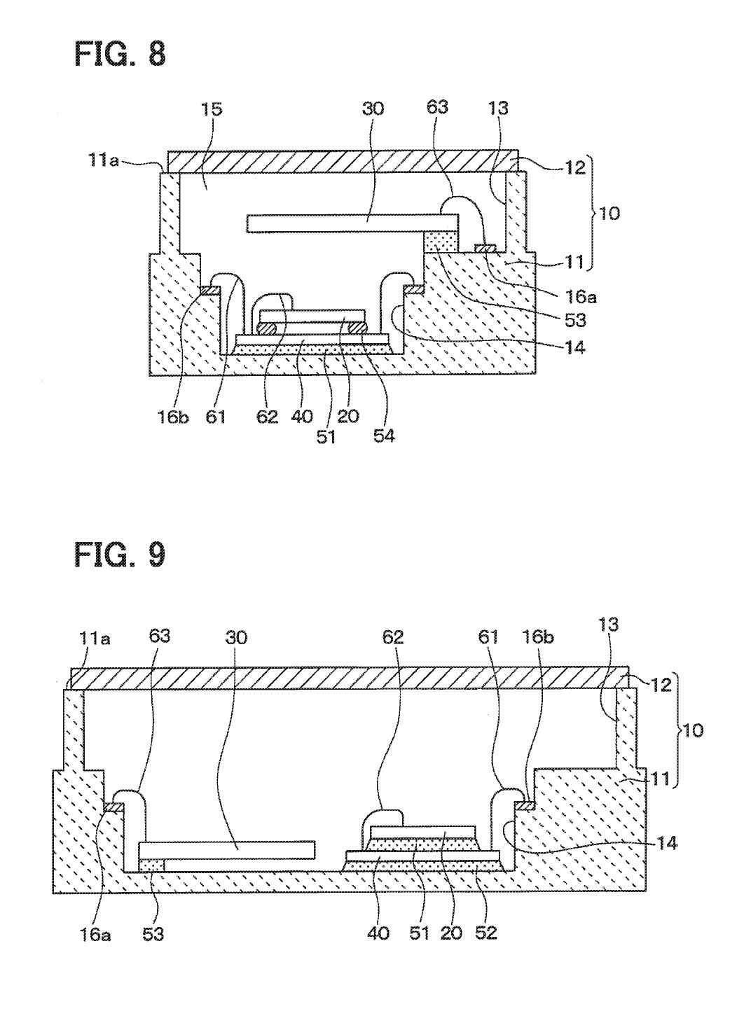

In the present embodiment, as is shown in FIG. 8, the bonding wire 62 electrically connecting the acceleration sensor 20 and the circuit board 40 is not included. Instead, the acceleration sensor 20 and the circuit board 40 are electrically and mechanically connected with metal bumps 54. In short, the acceleration sensor 20 is mounted to the circuit board 40 in the form of a flip chip. In the present embodiment, the metal bumps 54 correspond to a first connecting member.

Owing to the configuration as above, a transmission path of sensor signals outputted by the acceleration sensor 20 can be further shorter. Hence, reduction in detection accuracy due to a parasitic capacitance can be restricted further.

### Third Embodiment

A third embodiment of the present disclosure will be described. The present embodiment is same as the first embodiment above except that the angular velocity sensor 30 of the first embodiment is arranged on the bottom surface of the second recessed portion 14, and a description other than such a difference is omitted herein.

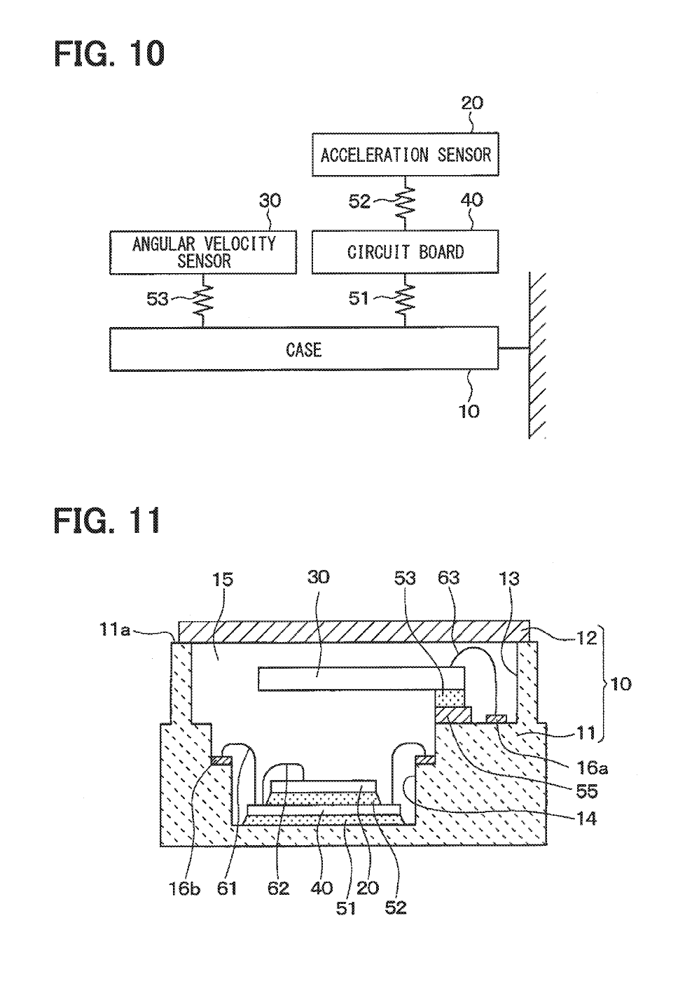

In the present embodiment, as is shown in FIG. 9, the angular velocity sensor 30 is arranged on a bottom surface of the second recessed portion 14 through the adhesive agent 53. Even when a physical quantity sensor is configured as above, as is shown in FIG. 10, sections that function as three springs, namely, the adhesive agent 53, the adhesive agent 51, and the adhesive agent 52 are situated between the angular velocity sensor 30 and the acceleration sensor 20. Hence, transmission of vibrations of the vibrating element 312 in the angular velocity sensor 30 to the acceleration sensor 20 can be restricted. Consequently, reduction in detection accuracy of the acceleration sensor 20 can be restricted.

In addition, because the angular velocity sensor 30 is arranged on the bottom surface of the second recessed portion 14, an increase of the physical quantity sensor in size in a height direction (stacking direction of the circuit board 40 and the acceleration sensor 20) can be restricted.

### Fourth Embodiment

A fourth embodiment of the present disclosure will be described. The present embodiment is same as the first embodiment above except that an anti-vibration portion is additionally situated between the adhesive agent 53 and the bottom surface of the first recessed portion 13 of the first embodiment above, and a description other than such a difference is omitted herein.

In the present embodiment, as is shown in FIG. 11, a metal member 55 serving as an anti-vibration portion formed of a metal lead wire or the like is situated between the adhesive agent 53 and a bottom surface of the first recessed portion 13. In other words, it can be said that two anti-vibration portions are situated between the angular velocity sensor 30 and the bottom surface of the first recessed portion 13 in the present embodiment.

Owing to the configuration as above, sections that function as four springs, namely, the adhesive agent 53, the metal member 55, the adhesive agent 51, and the adhesive agent 52 are situated between the angular velocity sensor 30 and the acceleration sensor 20. Hence, transmission of vibrations of the vibrating element 312 in the angular velocity sensor 30 to the acceleration sensor 20 can be restricted further. Consequently, reduction in detection accuracy of the acceleration sensor 20 can be restricted.

In addition, an adhesive agent too hard to function as a spring (to function as the anti-vibration portion) may be used as the adhesive agent 53. Even when a physical quantity sensor uses the adhesive agent 53 as above, sections that function as three springs, namely, the metal member 55, the adhesive agent 51, and the adhesive agent 52 are situated. Hence, an effect same as the effect of the first embodiment above can be obtained. That is to say, in a case where the angular velocity sensor 30 of the present embodiment uses the adhesive agent 53 that does not function as a spring, the adhesive agent 53 can be selected from a wider variety of options.

### Fifth Embodiment

A fifth embodiment of the present disclosure will be described. The present embodiment is same as the first embodiment above except that a beam portion 318 is provided between the vibrating element 312 and the outer peripheral portion 313 of the first embodiment above, and a description other than such a difference is omitted herein.

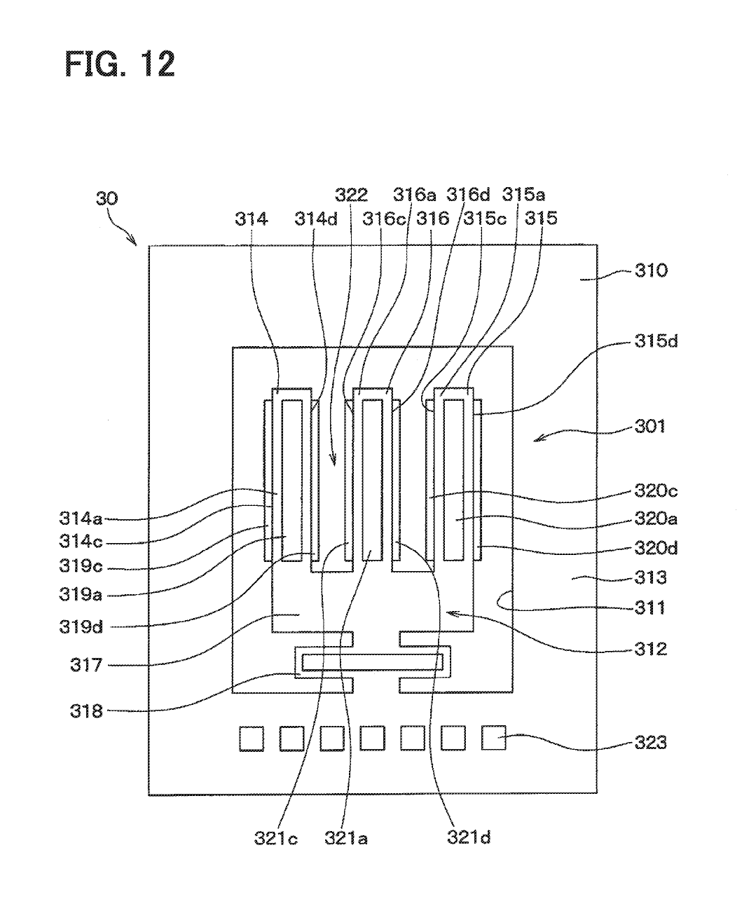

In the present embodiment, as is shown in FIG. 12, the beam portion 318 restricting transmission of stress and vibrations is provided between the vibrating element 312 and the outer peripheral portion 313. In short, the beam portion 318 as an anti-vibration portion is provided between the vibrating element 312 and the outer peripheral portion 313.

Owing to the configuration as above, because the beam portion 318 also functions as the anti-vibration portion, sections that function as four springs, namely, the beam portion 318, the adhesive agent 53, the adhesive agent 51, and the adhesive agent 52 are situated between the vibrating element 312 in the angular velocity sensor 30 and the acceleration sensor 20. Hence, transmission of vibrations of the vibrating element 312 in the angular velocity sensor 30 to the acceleration sensor 20 can be restricted further.

### Other Embodiments

The present disclosure is not limited to the embodiments mentioned above, and can be changed and modified to various embodiments which are also within the spirit and scope of the present disclosure.

For example, the respective embodiments above have described a case where the acceleration sensor 20 is packaged. However, the angular velocity sensor 30 may be packaged instead. In such a case, the housing space 15 is set to an atmospheric pressure and an airtight chamber in which to seal the sensing portion 322 of the angular velocity sensor 30 is set to a vacuum pressure. Alternatively, both of the acceleration sensor 20 and the angular velocity sensor 30 may be packaged. In such a case, the housing space 15 may be at either an atmospheric pressure or a vacuum pressure.

In the respective embodiments above, the angular velocity sensor 30 may be other than a tripod-type tuning fork. For example, the angular velocity sensor 30 may be a so-called T-type tuning fork in which the first drive reed 314, the second drive reed 315, and the detection reed 316 protrude to both sides with the base portion 317 in between. Further, the angular velocity sensor 30 may be a so-called H-type tuning fork or a normal tuning fork. That is to say, a configuration of the angular velocity sensor 30 is not particularly limited as long as an angular velocity is detected while the vibrating element 312 is vibrating.

In the respective embodiments above, the acceleration sensor 20 may be of a piezoelectric type.

Further, in the respective embodiments above, the angular velocity sensor 30 may be electrically and mechanically connected to an internal connecting terminal 16a with a metal bump. In short, the angular velocity sensor 30 may be mounted in the form of a flip chip.

The respective embodiments above may be combined appropriately.

For example, the beam portion 318 may be provided between the vibrating element 312 and the outer peripheral portion 313 by combining the fifth embodiment with any one of the second through fourth embodiments.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A physical quantity sensor, comprising:
an acceleration sensor outputting a sensor signal corresponding to acceleration;
an angular velocity sensor having a vibrating element made of a piezoelectric material, generating charges corresponding to an angular velocity when the angular velocity is applied while the vibration element is vibrating, and outputting a sensor signal corresponding to the charges;
a circuit board performing predetermined processing on the angular velocity sensor and the acceleration sensor;
a housing portion provided with a recessed portion in a surface of the housing portion to house the acceleration sensor, the angular velocity sensor, and the circuit board in the recessed portion; and
an anti-vibration portion situated between the housing portion and the vibrating element in the angular velocity sensor, wherein
the angular velocity sensor and the acceleration sensor are spaced apart,
the circuit board is arranged on a bottom surface of the recessed portion through a first connecting member, and
the acceleration sensor is stacked on the circuit board through a second connecting member, wherein
the anti-vibration portion is a metal member situated between the angular velocity sensor and the housing portion.

2. The physical quantity sensor according to claim 1, further comprising
an additional anti-vibration portion that is situated between the angular velocity sensor and the metal member.

3. The physical quantity sensor according to claim 2, wherein
the additional anti-vibration portion is an adhesive agent.

4. The physical quantity sensor according to claim 1, wherein
the acceleration sensor and the circuit board are electrically connected through a wire, and
the second connecting member connects the acceleration sensor and the circuit board only mechanically.

5. The physical quantity sensor according to claim 1, wherein
the angular velocity sensor is arranged above the acceleration sensor.
